(19) United States
(12) Patent Application Publication
(10) Pub. No.: US 2009/0285039 A1
(43) Pub. Date: Nov. 19, 2009

(54) METHOD AND APPARATUS FOR LOCALLY GENERATING A VIRTUAL GROUND FOR WRITE ASSIST ON COLUMN SELECTED SRAM CELLS

(75) Inventors: Chad Allen Adams, Byron, MN (US); Elizabeth Lair Gerhard, Rochester, MN (US); Sharon Huertas Cesky, Rochester, MN (US); Jeffrey Milton Scherer, Rochester, MN (US)

Correspondence Address: IBM-ACC-Washington;c/o Myers Andras Sherman LLP, 19900 MacArthur Blvd., Suite 1150, Irvine, CA, 92612, US

(73) Assignee: International Business Machines Corporation, Armonk, NY (US)

(21) Appl. No.: 12/121,553

(22) Filed: May 15, 2008

(51) Int. Cl. G11C 7/00

(52) U.S. Cl. 365/189.11

(57) ABSTRACT

A method and apparatus for write assist for a static random access memory (SRAM) array, is provided, which increases the write ability of the SRAM cell by locally raising the source voltage. One embodiment involves locally generating a virtual ground for write assist on column selected SRAM cells, including locally raising the source voltage to increase the write ability of the SRAM cell; wherein locally raising the source voltage comprises locally generating a virtual source/ground node for boosting the write ability of a column of SRAM cells without using an additional on-chip or off-chip supply; thereby decreasing the voltage differential across the source and supply of the column of SRAM cells during a write, and restoring the standard chip differential during a read.

### BACKGROUND OF THE INVENTION

1. Field of the Invention

The present invention relates generally to memory devices, and in particular to write assist on memory devices.

2. Background Information

With conventional technologies it has become increasingly difficult to design static random access memory (SRAM) cells that are both stable and writeable. Due to small device variations, the design centering window for these functions has greatly narrowed. One technique for expanding the design centering window involves decreasing the voltage differential across the source and supply of the SRAM cell during a write, and restoring the standard chip differential during a read. During a write operation this is achieved by either lowering the supply voltage or raising the source voltage (or a combination of both). Conventional techniques employ an additional supply or an off-chip device such as a voltage regulator to achieve this functionality. However, additional on-chip supplies and/or off-chip devices are costly and power prohibitive.

### SUMMARY OF THE INVENTION

The invention provides a method and apparatus for write assist for a static random access memory (SRAM) array, which increases the write ability of the SRAM cell by locally raising the source voltage. One embodiment involves locally generating a virtual ground for write assist on column selected SRAM cells, including locally raising the source voltage to increase the write ability of the SRAM cell; wherein locally raising the source voltage comprises locally generating a virtual source/ground node for boosting the write ability of a column of SRAM cells without using an additional on-chip or off-chip supply; thereby decreasing the voltage differential across the source and supply of the column of SRAM cells during a write, and restoring the standard chip differential during a read.

Other aspects and advantages of the present invention will become apparent from the following detailed description, which, when taken in conjunction with the drawings, illustrate by way of example the principles of the invention.

### BRIEF DESCRIPTION OF THE DRAWINGS

For a fuller understanding of the nature and advantages of the invention, as well as a preferred mode of use, reference should be made to the following detailed description read in conjunction with the accompanying drawings, in which:

FIG. 1 shows a circuit for locally generating a virtual ground for write assist on column selected SRAM cells, according to an embodiment of the invention.

FIG. 2 shows example waveforms of the circuit of FIG. 1.

### DESCRIPTION OF THE PREFERRED EMBODIMENTS

The following description is made for the purpose of illustrating the general principles of the invention and is not meant to limit the inventive concepts claimed herein. Further, particular features described herein can be used in combination with other described features in each of the various possible combinations and permutations. Unless otherwise specifically defined herein, all terms are to be given their broadest possible interpretation including meanings implied from the specification as well as meanings understood by those skilled in the art and/or as defined in dictionaries, treatises, etc.

The invention provides a method and apparatus for write assist for a static random access memory (SRAM) array, which increases the write ability of the SRAM cell by locally raising the source voltage. One embodiment involves locally generating a virtual ground for write assist on column selected SRAM cells, including locally raising the source voltage to increase the write ability of the SRAM cell; wherein locally raising the source voltage comprises locally generating a virtual source/ground node for boosting the write ability of a column of SRAM cells without using an additional on-chip or off-chip supply; thereby decreasing the voltage differential across the source and supply of the column of SRAM cells during a write, and restoring the standard chip differential during a read.

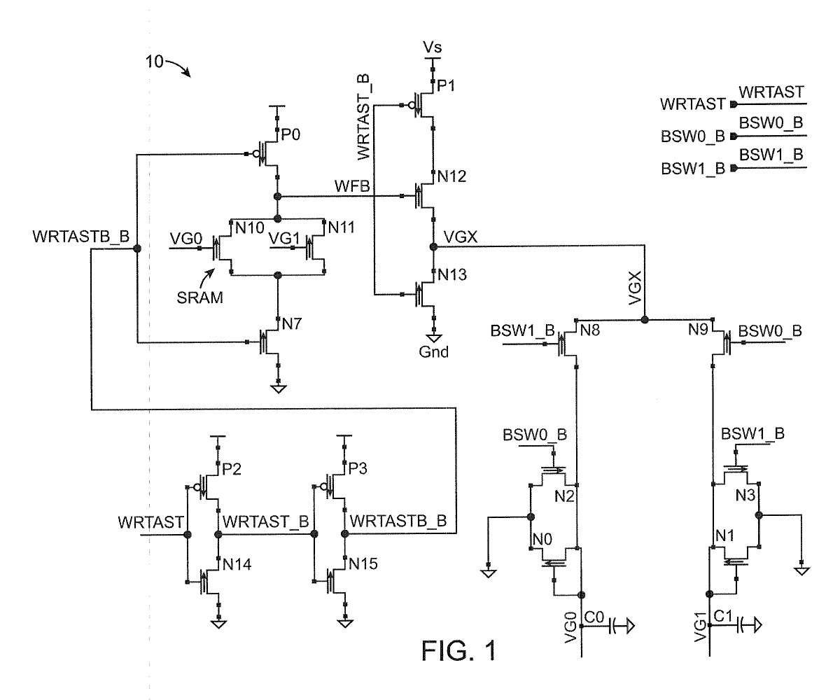

FIG. 1 shows an example circuit diagram 10 for local (e.g., on-chip) virtual ground generation, with a column decode of 2, for write assist for a static random access memory (SRAM) cell, according to an embodiment of the invention. While the circuit is depicted with a column decode of 2, with minor adjustments it may be used for other column decode options. In FIG. 1, a set of devices N10, N8, N2, N0 and a set of devices N11, N9, N3, N1, are the two sets of devices for the two outputs VG0 and VG1.

In FIG. 1, VG0 and VG1 depict the ground/source of each bit SRAM column which are then selected by BSW0_B and BSW1_B signals, respectively. The circuit operation, which is the same for writing both columns, is as follows. For STANDBY or READ operation (mode), WRTAST is held LOW, and BSW0_B and BSW1_B are held HIGH. In this case, VG0 and VG1 are held LOW through n-channel transistor devices N2 and N3, respectively.

For WRITE operation (e.g., WRITE COLUMN 0), a signal WRTAST transitions HIGH, and BSW0_B signal transitions LOW, while a signal BSW1_B is held HIGH. Thus n-channel transistor device N9 is disabled and VG1 is isolated. Meantime, with pulldown device N2 also disabled, the signal VG0 tracks a signal VGX.

Before WRTAST goes high, in STANDBY or READ operation, WRTAST was held LOW and WFB was held HIGH through a p-channel transistor device P0, thus enabling n-channel transistor device N12.

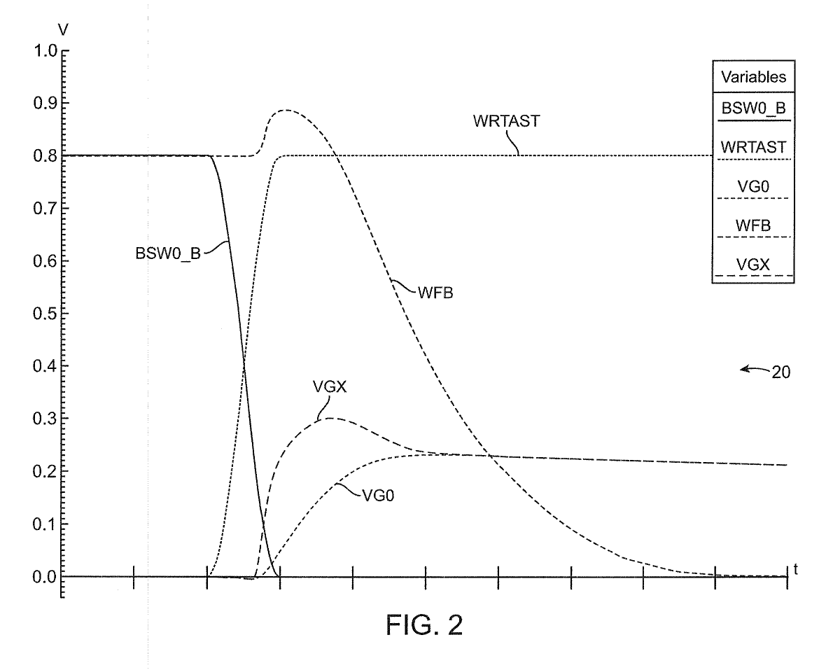

FIG. 2 shows a graph 20 of example operation waveforms WRTAST, WFB, VGX, VG0, and BSW0_B, of the circuit. In the WRITE operation, WRTAST transitions HIGH causing node WFB to float and leaving the device N12 weakly enabled.

With WRTAST at HIGH (WRTAST_B is LOW), a p-channel transistor device P1 is enabled and the path to ground (Gnd) through n-channel transistor device N13 is disabled, thereby allowing node VGX to collect charge.

As the collected charge approaches a NFET threshold voltage, the VG0 gate connected n-channel transistor device N10 begins to turn on. This pulls node WFB to ground, disabling device N12 and terminating the path to the supply voltage Vs.

Throughout the WRITE operation, the diode connected devices N0 and N1 provide protection on the bit lines and will be enabled if VG0 or VG1 increase above the NFET threshold voltage.

As shown by an example in FIG. 2, WFB slowly discharges through device N10 until device N12 turns off and VGX settles to around 200 mV.

As is known to those skilled in the art, the aforementioned example embodiments described above, according to the present invention, can be implemented in many ways, such as program instructions for execution by a processor, as software modules, as computer program product on computer readable media, as logic circuits, as silicon wafers, as integrated circuits, as application specific integrated circuits, as firmware, etc. Though the present invention has been described with reference to certain versions thereof; however, other versions are possible. Therefore, the spirit and scope of the appended claims should not be limited to the description of the preferred versions contained herein.

Those skilled in the art will appreciate that various adaptations and modifications of the just-described preferred embodiments can be configured without departing from the scope and spirit of the invention. Therefore, it is to be understood that, within the scope of the appended claims, the invention may be practiced other than as specifically described herein.

What is claimed is:

1. A method of write assist for a static random access memory (SPAM) array, comprising:
locally generating a virtual ground for write assist on column selected SRAM cells, including locally raising the source voltage to increase the write ability of the SRAM cell;
wherein locally raising the source voltage comprises locally generating a virtual source/ground node for boosting the write ability of a column of SRAM cells without using an additional on-chip or off-chip supply;
thereby allowing decreasing the voltage differential across the source and supply of the column of SPAM cells during a write, and restoring the standard chip differential during a read.
